(19) United States
(12) Patent Application Publication
(10) Pub. No.: US 2008/0041562 A1
(43) Pub. Date: Feb. 21, 2008

(54) Airflow bypass and cooling of processors in series

(75) Inventor: Rakesh Bhatia, Sunnyvale, CA (US)

Correspondence Address: OSHA LIANG L.L.P./SUN, 1221 MCKINNEY, SUITE 2800, HOUSTON, TX, 77010, US

(73) Assignee: Sun Microsystems, Inc.

(21) Appl. No.: 11/506,341

(22) Filed: Aug. 18, 2006

(51) Int. Cl. H05K 7/20

(52) U.S. Cl. 165/80.3; 361/704

(57) ABSTRACT

A method for cooling electronic components includes disposing a first cooling structure associated with a first processor in a chassis, disposing a second cooling structure associated with a second processor in the chassis, and configuring the first cooling structure and the second cooling structure such that air propagating through the chassis includes air that passes through the first cooling structure and the second cooling structure, and air that passes only through the second cooling structure.

### BACKGROUND

A computer system operates under the control of numerous integrated circuits (“ICs”). In operation, an integrated circuit dissipates heat as a result of work performed by the integrated circuit. Energy that is needed by the integrated circuit for work is not consumed with 100% efficiency. Thus, excess energy is released, among other things, as heat. As integrated circuits become more dense (i.e., more transistors per unit area) and faster (i.e., higher operating frequencies), they generate more heat. As excessive heat is damaging to an integrated circuit both in terms of performance and component integrity, an important design consideration involves ensuring that heat dissipated by an integrated circuit is sufficiently drawn away from the integrated circuit, where the efficiency of drawing away heat from the integrated circuit is expressed in terms of what is referred to as the “heat transfer rate.”

The computing portion of a computer system is typically housed in an enclosure known as a chassis. A chassis provides protection from factors such as dust and electromagnetic interference. “Heat sinks” are devices that are commonly used to cool integrated circuits. A heat sink is often used with an integrated circuit housed in a package atop a substrate. The heat sink is made of a high thermal conductivity metal (e.g., copper or aluminum). A “high thermal conductivity metal” is one that allows heat to pass through it because it contains many free electrons.

The base of a heat sink is secured over an integrated circuit by, for example, a retention clip or an adhesive or thermal interface material. During operation of the integrated circuit, the temperature of the integrated circuit increases due to increased particle movement resulting from a build-up of excess energy. The increased integrated circuit temperature results in an increase in the temperature of the package, and consequently, of the heat sink. The increased temperature of the heat sink results in an increase in the temperature of the air around the heat sink, whereby the heated air rises and effectively draws heat away from the integrated circuit. This process is referred to as “convection.”

The removal of heat dissipated from an integrated circuit by a heat sink is dependent on a number of factors. For example, the thermal resistance of the package that houses the integrated circuit affects how much heat transfers from the integrated circuit to the heat sink. Also, the effectiveness of the adhesives between the integrated circuit and its package and the package and the heat sink affects how much heat transfers between these components. Moreover, the conductivity of the materials used in the package and the heat sink has a direct bearing on the amount of heat that is transferred away from the integrated circuit. The surface area of the heat sink is also important as more surface area results in more air being heated, thereby resulting in more heat being drawn away from the integrated circuit by the rising heated air. Efficient cooling approaches are critical to the performance and reliability of an IC device with significant power consumption.

### SUMMARY OF INVENTION

In general, in one aspect, the invention relates to an apparatus including a first processor in a chassis, a first cooling structure associated with the first processor, a second processor in the chassis, and a second cooling structure associated with the second processor, where the first cooling structure and the second cooling structure are configured such that air passing through the chassis includes air that passes through the first cooling structure and the second cooling structure, and air that passes only through the second cooling structure.

In general, in one aspect, the invention relates to a method for cooling electronic components, including disposing a first cooling structure associated with a first processor in a chassis, disposing a second cooling structure associated with a second processor in the chassis, and configuring the first cooling structure and the second cooling structure such that air propagating through the chassis includes air that passes through the first cooling structure and the second cooling structure, and air that passes only through the second cooling structure.

In general, in one aspect, the invention relates to means for cooling electronic components, including means for disposing a first cooling structure associated with a first processor in a chassis, means for disposing a second cooling structure associated with a second processor in the chassis, and means for configuring the first cooling structure and the second cooling structure such that air propagating through the chassis includes air that passes through the first cooling structure and the second cooling structure, and air that passes only through the second cooling structure.

Other aspects and advantages of the invention will be apparent from the following description and the appended claims.

### BRIEF DESCRIPTION OF DRAWINGS

FIG. 1 shows a computer system in accordance with one or more embodiments of the invention.

FIG. 2A shows a side view of an apparatus in accordance with one or more embodiments of the invention.

FIG. 2B shows a side view of an apparatus in accordance with one or more embodiments of the invention.

FIG. 3A shows a perspective view of an apparatus in accordance with one or more embodiments of the invention.

FIG. 3B shows a perspective view of an apparatus in accordance with one or more embodiments of the invention.

FIG. 4A shows a plan view of an apparatus in accordance with one or more embodiments of the invention.

FIG. 4B shows a plan view of an apparatus in accordance with one or more embodiments of the invention.

FIG. 5 shows a perspective view of an apparatus in accordance with one or more embodiments of the invention.

FIG. 6 shows a method for cooling a plurality of processors in accordance with one or more embodiments of the invention.

### DETAILED DESCRIPTION

Exemplary embodiments of the invention will be described with reference to the accompanying figures. Like items in the figures are shown with the same reference numbers. Further, the use of “ST” in the figures is equivalent to the use of “Step” in the detailed description below.

In embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

Embodiments of the invention relate to methods and apparatus for cooling a plurality of electronic devices. More specifically, one or more embodiments of the invention relate to methods and apparatus for cooling a plurality of processors in a computer system.

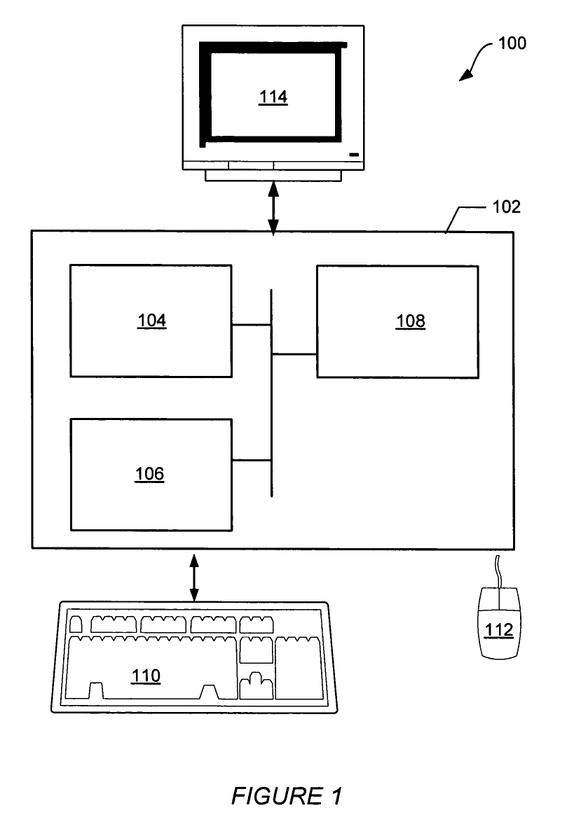

FIG. 1 shows a computer system (100) in accordance with one or more embodiments of the invention. The computer system (100), as shown in FIG. 1, includes several components that are collectively used by a user to perform various functions. With the computer system (100), the user may input data to a computing portion (102) using peripheral devices such as a keyboard (110) or a mouse (112). Data may also be provided to the computing portion (102) using data storage media (e.g., a floppy disk or a CD-ROM (not shown)). The computer system (100) may be connected to a local area network (LAN) or a wide area network (e.g., the Internet) (not shown) via a network interface connection (not shown). Those skilled in the art will appreciate that these input and output means may take other forms.

As shown in FIG. 1, the computing portion (102) is typically housed in a chassis, which may be rack-mountable or free-standing. Additionally, the computing portion (102) may contain a plurality of circuit boards (104, 106, 108) (e.g., printed circuit boards (PCBs) or printed wiring boards (PWBs)), on which various circuit components are implemented. For example, a circuit board known as a motherboard typically houses a processor and associated memory for the computer system (100). The computing portion (102), using a processor, memory and other internal components, processes both internal data and data provided to the computing portion (102) by a user to generate data requested by the user. The generated data may be provided to the user via, for example, a display device (114) or a printer (not shown).

The computing portion (102) of a computer system also typically includes various components such as, for example, a power supply, disk drives, and the electrical circuitry required to perform the necessary and requested operations of the computer system. However, some components may be located external to the chassis of the computing portion (102) due to size, temperature, or other constraints. Many of the components in the computing portion (102) generate heat as they operate. In accordance with one or more embodiments of the invention, in order to cool a semiconductor device such as an integrated circuit (e.g., a processor) in a chassis, heat sinks and fans may be used. The design of the heat sinks may be balanced with the air flow properties in the chassis such that a near-maximum cooling of the heat sinks, and thus, the processors, is achieved.

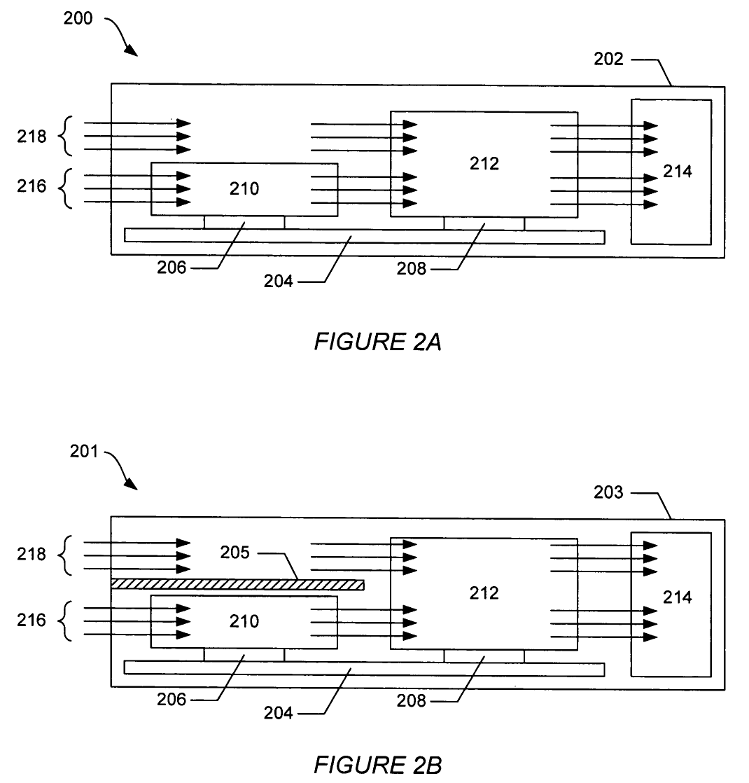

FIG. 2A shows an apparatus (200) in accordance with one or more embodiments of the invention. Specifically, FIG. 2A shows a chassis (202) of a computer system with a number of electronic components. Inside the chassis (202) is a circuit board (204), having a first semiconductor device (206) and a second semiconductor device (208). The first and second semiconductor devices are disposed in a serial orientation with respect to airflow in the chassis, as seen with respect to air flow (216, 218). Located on the first semiconductor device (206) is a first cooling structure (210), and located on the second semiconductor device (208) is a second cooling structure (212), which has a greater height than the first cooling structure (210). A fan (214) increases air flow by drawing air through the chassis (202), and through the first cooling structure (210) and the second cooling structure (212) to cool the first and second semiconductor devices (206, 208).

One skilled in the art will appreciate that the aforementioned components of apparatus (200) may differ from those discussed with respect to FIG. 2A without departing from the nature of the invention. For example, in one or more embodiments of the invention, the circuit board (200) is a motherboard of a computer system. Similarly, the semiconductor devices (206, 208) may be any device that requires cooling, such as, for example, transistors, microprocessors, etc. Further, cooling structures (210, 212) may be any device to cool a semiconductor device that is aided by air flow in a chassis, such as, for example, a heat sink, a heat pipe, etc., or a combination thereof.

As seen with respect to FIG. 2A, a portion of the air (216) drawn into the chassis (202) passes through both the first cooling structure (210) and the second cooling structure (212). The portion of the air (216) that passes through both cooling structures passes through the first cooling structure (210) to cool the first semiconductor device (206), and then it passes through the second cooling structure (212) to cool the second semiconductor device (208).

As a result of passing through the first cooling structure (210), the air (216) cools the first semiconductor device (206). However, as the first semiconductor device (206) is cooled, the air (216) is heated. Thus, when the air (216) leaves the first cooling structure (210), it is warmer than when it entered the first cooling structure (210). Thus, when the air (216) reaches the second cooling structure (212), which is “downstream” from the first cooling structure (210), it is warmer than before it passed through the first cooling structure (210).

After the air (216) leaves the first cooling structure (210), the air (216) is directed to the second cooling structure (212). The air (216) passes through the second cooling structure (212), and as a result of passing through the second cooling structure (212), the air (216) cools the second semiconductor device (208). However, because the air (216) is warmer than it was before it passed through the first cooling structure (210), the second semiconductor device (208) may not be cooled as much as the first semiconductor device (206) by air (216).

Accordingly, a second portion of the air (218) drawn into the chassis (202) passes only through the second cooling structure (212). Because the air (218) did not pass though the first cooling structure (210) to cool the first semiconductor device (206), the second portion of the air (218) it is cooler than the air (216) that also passed through the first cooling structure (210) at the point where the air (216, 218) enters the second cooling structure (212). In other words, the geometries of the first and second cooling structures are such that only a portion of the incoming air flows over or through a leading cooling structure (i.e., first cooling structure (210)), while a greater portion of the incoming air flows over or through a trailing cooling structure (i.e., second cooling structure (212)).

As a result of passing through the second cooling structure (212), the second portion of the air (218), with the air (216) that also passed through the first cooling structure (210), cools the second semiconductor device (208). As the second semiconductor device (208) is cooled, the air (216, 218) is heated. Thus, when the air (216, 218) leaves the second cooling structure (212), it is warmer than when it entered the second cooling structure (212), but the second semiconductor device (208) is cooled.

One skilled in the art will appreciate that while air flow has been depicted from front-to-rear with respect to the chasses (202, 203) in FIGS. 2A and 2B, air flow is also possible from rear-to-front, or from side-to-side in the chasses (202, 203), depending on the orientation of the semiconductor devices and the associated cooling structures contained therein.

FIG. 2B shows an apparatus (201) in accordance with one or more embodiments of the invention. Like the apparatus (200) of FIG. 2B, the apparatus (201) of FIG. 2 includes a chassis (203) and a circuit board (204). On the circuit board (204) is a first semiconductor device (206) and a second semiconductor device (208). Located on the first semiconductor device (206) is a first cooling structure (210), and located on the second semiconductor device (208) is a second cooling structure (212), which has a greater height than the first cooling structure (210). A fan (214) draws air through the chassis (202), and through the first cooling structure (210) and the second cooling structure (212) to cool the first and second semiconductor devices (206, 208).

As seen in FIG. 2B, a duct (205) separates air (216) that passes through both the first cooling structure (210) and the second cooling structure (212) from air (218) that passes only through the second cooling structure (212). Thus, air (216) that passes through the first cooling structure (210) does not mix with air (218) that only passes through the second cooling structure (212) until the air (216, 218) passes the duct (205). The duct (205) may be an integral part of the chassis (i.e., the duct may be formed as part of the chassis), or the duct may be formed to be removable from the chassis (203). One skilled in the art will appreciate that the duct may be formed from any suitable material, such as, for example, plastic, metal, etc.

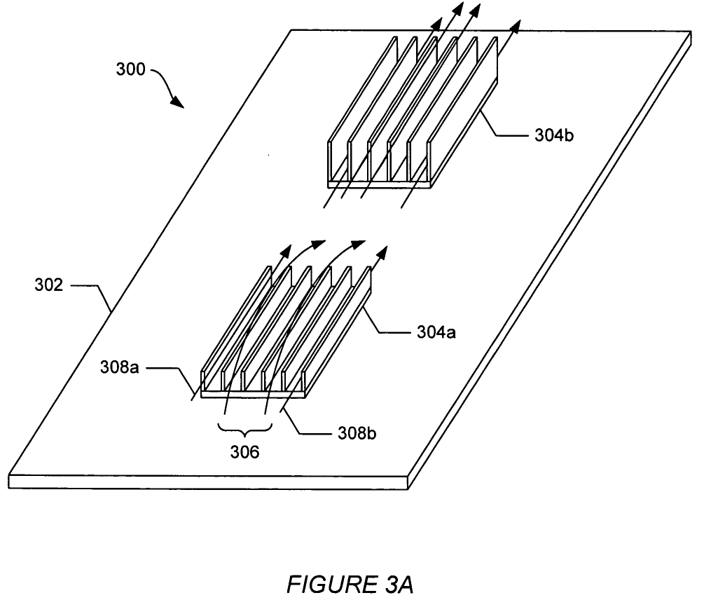

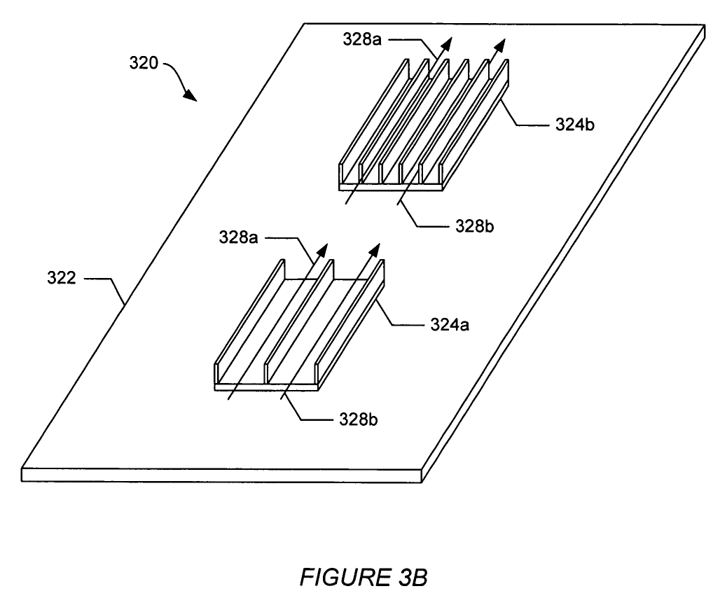

FIG. 3A shows an apparatus (300) in accordance with one or more embodiments of the invention. Specifically, FIG. 3A shows a perspective view of a motherboard (302) having two processors (hidden from view; not shown) and two heat sinks (304a, 304b) in accordance with one or more embodiments of the invention. The second heat sink (304b) is taller than the first heat sink (304a), and thus has a greater surface area than the first heat sink (304a). In other words, the second heat sink (304b) has a greater fin area than the first heat sink (304a), which allows for more heat to be drawn from the second processor. Air (306, 308a, 308b) is drawn across the heat sinks (304a, 304b) to cool the two processors. As seen with respect to FIG. 3A, some of the air (308a, 308b) passes through both heat sinks (304a, 304b). However, because the second heat sink (304b) is taller than the first heat sink (304a), some of the air (306) does not pass through the first heat sink (304a), and only passes through the second heat sink (304b).

Thus, a portion of the air (308a, 308b) passes through the first heat sink (304a) and cools the first processor, and then passes through the second heat sink (304b) and cools the second processor. This portion of the air (308a, 308b) is warmer when it passes through the second heat sink (304b) than it is when it passes through the first heat sink (304a). To further cool the second heat sink (304b), air (306) that bypasses the first heat sink (304a) (i.e., is not used to cool the first heat sink (304a)) is used to cool the second heat sink (304b). In effect, these two portions of air (306; 308a, 308b) mix at the leading edge of the second heat sink (304b) to create an airflow that is warmer than the air that only passes through the second heat sink (304b), but is cooler than the portion of the air (308a, 308b) that first passes through the first heat sink (304a).

Alternatively, as shown in FIG. 3B, a heat sink that is part of an apparatus (320) in accordance with one or more embodiments of the invention may have a greater fin area than another heat sink by having more fins than the other heat sink. FIG. 3B shows a perspective view of a motherboard (322) in accordance with one or more embodiments of the invention having two processors (hidden from view; not shown) and two heat sinks (324a, 324b). The second heat sink (324b) has more fins than the first heat sink (324a) (i.e., a smaller fin pitch), and thus has a greater surface area than the first heat sink (324a). In other words, like the apparatus of FIG. 3A, the second heat sink (324b) has a greater fin area than the first heat sink (324a), which allows for more heat to be drawn from the second processor. Air (328a, 328b) is drawn across the heat sinks (324a, 324b) to cool the two processors. As seen with respect to FIG. 3B, some of the air (328a, 328b) passes through both heat sinks (324a, 324b). However, because the second heat sink (324b) has a smaller fin pitch than the first heat sink (324a), the air (328a, 328b) does not cool the first heat sink (324a) as much as it cools the second heat sink (324b).

Thus, a portion of the air (328a, 328b) passes through the first heat sink (324a) and cools the first processor, and then passes through the second heat sink (324b) and cools the second processor. This portion of the air (328a, 328b) is warmer when it passes through the second heat sink (324b) than it is when it passes through the first heat sink (324a). To further cool the second heat sink (324b), more fins are present on the second heat sink (324b).

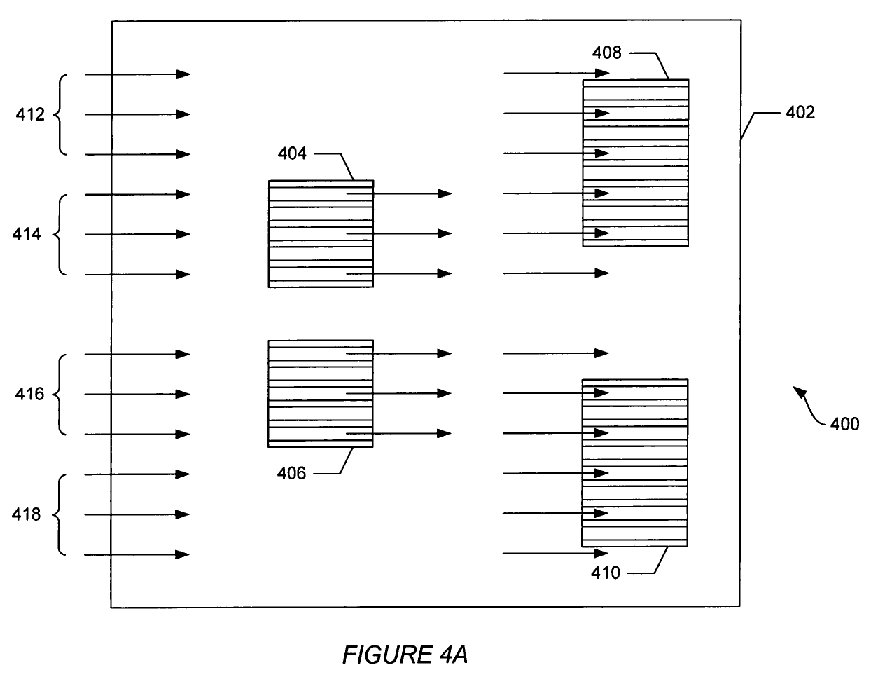

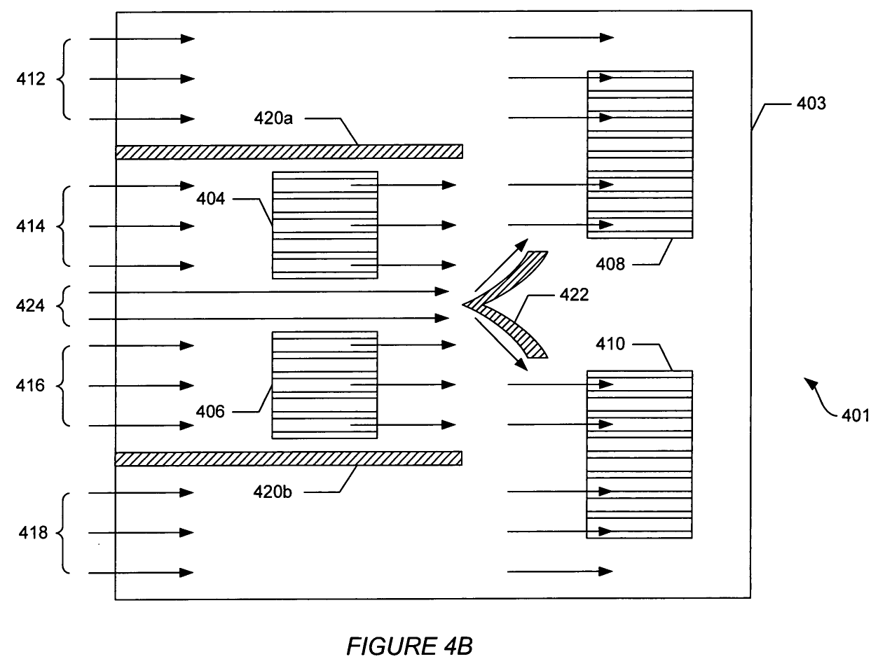

FIG. 4A shows an apparatus (400) in accordance with one or more embodiments of the invention. Specifically, FIG. 4 shows a plan view of a motherboard (402) having four processors (hidden from view; not shown) and four heat sinks (404, 406, 408, 410) in accordance with one or more embodiments of the invention. The third and fourth heat sinks (408, 410) are wider than the first and second heat sinks (404, 406). Air (412, 414, 416, 418) is drawn across the heat sinks (404, 406, 408, 410) to cool the four processors. As seen with respect to FIG. 4A, some of the air (414, 416) passes through all four heat sinks (404, 406, 408, 410). However, because the third and fourth heat sinks (408, 410) are wider than the first and second heat sinks (404, 406), some of the air (412, 418) does not pass through the first and second heat sink (404, 406), and only passes through the third and fourth heat sinks (408, 410).

Thus, a portion of the air (414, 416) passes through the first and second heat sinks (404, 406) and cools the first and second processors, and then passes through the third and fourth heat sinks (408, 410) and cools the third and fourth processors. This portion of the air (414, 416) is warmer when it passes through the third and fourth heat sinks (408, 410) than it is when it passes through the first and second heat sinks (404, 406). Therefore, to further cool the third and fourth heat sinks (408, 410), air (412, 418) that bypasses the first and second heat sinks (404, 406) (i.e., air that is not used to cool the first heat sink (404) or the second heat sink (406)) is used to cool the third and fourth heat sinks (408, 410). As discussed with respect to FIG. 3A, these portions of air (412, 414, 416, 418) mix at the leading edge of the third and fourth heat sinks (408, 410) to create an airflow that is cooler than the air (414, 416) that first passes through the first heat sink (404) or the second heat sink (406), but is warmer than the air (412, 418) that only passes through the third heat sink (408) or the fourth heat sink (410).

FIG. 4B shows an apparatus (401) in accordance with one or more embodiments of the invention. Like the apparatus (400) of FIG. 4A, the apparatus (401) of FIG. 4B includes a motherboard (403), four processors (not shown), and four heat sinks (404, 406, 408, 410). Additionally, motherboard (403) includes ducts (420a, 420b, 422). As seen in FIG. 4B, first and second ducts (420a, 420b) separate air (414, 416) that passes through both the first and second heat sinks (404, 406) and the third and fourth heat sinks (408, 410) from air (412, 418) that passes only through the third and fourth heat sinks (408, 410). Thus, air (414, 416) that passes through all four heat sinks does not mix with air (118) that only passes through the third and fourth heat sinks (408, 410) until the air (412, 414) passes the first duct (420a) and air (416, 418) passes the second duct (420b).

The third duct (422) routes air (414, 416, 424) that may have otherwise not passed through the third and fourth heat sinks (408, 410) toward the third and fourth heat sinks (408, 410). Similarly, ducts (not shown) may be placed at the edges of the motherboard (403) to route air (e.g., 412, 418) that may have otherwise not passed through the third and fourth heat sinks (408, 410) from the edges of the motherboard (403) toward the third and fourth heat sinks (408, 410). As discussed with reference to FIG. 4A, air passes through the heat sinks (404, 406, 408, 410); however, the addition of the ducts allows for a specific direction or separation of air in the chassis (403).

As discussed with reference to FIG. 2B, the ducts (420a, 420b, 422) may be integral part of a chassis or motherboard (i.e., the duct may be formed as part of the chassis or motherboard), or the ducts may be formed to be removable from a chassis or motherboard. One skilled in the art will appreciate that the ducts may be formed from any suitable material, such as, for example, plastic, metal, etc.

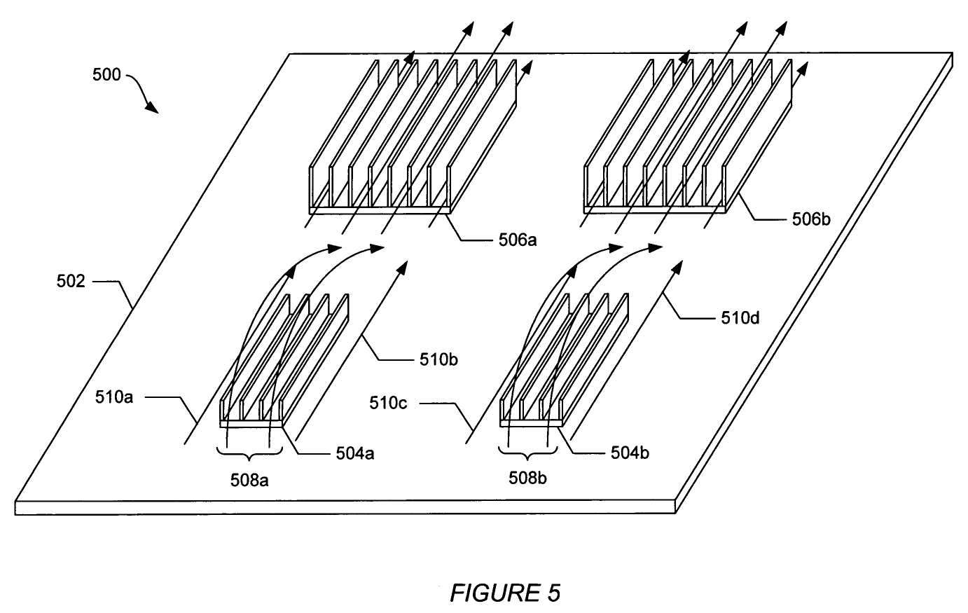

FIG. 5 shows an apparatus (500) in accordance with one or more embodiments of the invention. Specifically, FIG. 5 shows a perspective view of a motherboard (502) having four processors (hidden from view; not shown) and four heat sinks (504a, 504b, 506a, 506b) in accordance with one or more embodiments of the invention. The third and fourth heat sinks (506a, 506b) are taller and wider than the first and second heat sinks (504a, 504b), providing a larger surface area to draw more heat from the third and fourth processors. Thus, the third and fourth heat sinks (506a, 506b) have a greater fin area than the first and second heat sinks (504a, 504b).

As discussed with respect to FIG. 3A, a portion of the air (not shown) passes through the first heat sink (504a) and cools the first processor, and then passes through the third heat sink (506a) and cools the third processor. Similarly, a portion of the air (not shown) passes through the second heat sink (504b) and cools the second processor, and then passes through the fourth heat sink (504b) and cools the fourth processor. However, because the first and second heat sinks (504a, 504b) are shorter and narrower than the third and fourth heat sinks (506a, 506b), air (508a, 508b, 510a, 510b, 510c, 510d) that does not pass through the first and second heat sinks (504a, 504b) may pass through the third and fourth heat sinks (506a, 506b) to cool the third and fourth processors (not shown).

This portion of the air (508a, 508b, 510a, 510b, 510c, 510d) is mixes with the air that also passes through the first and second heat sinks (504a, 504b) to create an airflow that is warmer than the air that only passes through the third and fourth heat sinks (506a, 506b), but is cooler than the air that first passes through the first and second heat sinks (504a, 504b).

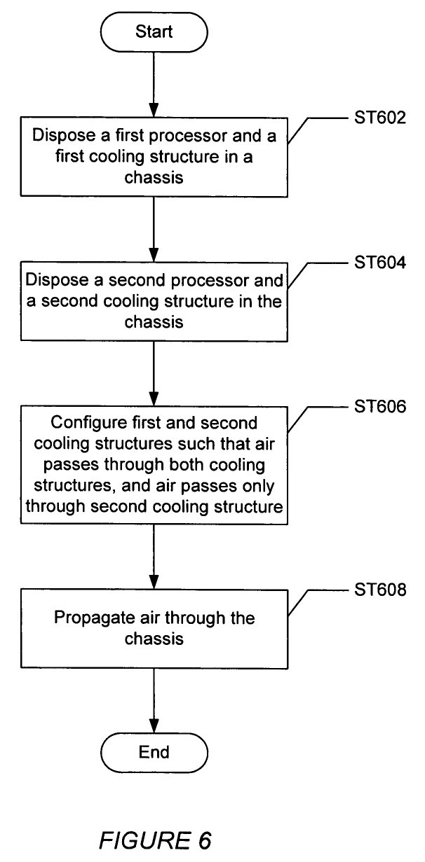

FIG. 6 shows a method for cooling a electronic components in accordance with one or more embodiments of the invention. As seen with respect to FIG. 6, a first processor and a first cooling structure associated with the first processor are disposed in a chassis (Step 602). Then, a second processor and a second cooling structure associated with the second processor are disposed in a chassis (Step 604). The first and second processors and the first and second cooling structures may be disposed, for example, on a circuit board, a motherboard, etc. The first and second cooling structures are configured such that air passes through both cooling structures, and air passes only through the second cooling structure (Step 606). Further, in one or more embodiments of the invention, air is propagated through the chassis (Step 608). Air that propagates through the chassis may pass through one or more of the first and second cooling structures, thereby cooling one or more of the first and second processors.

In one or more embodiments of the invention, a greater number of semiconductor devices may be placed on a circuit board by placing the semiconductor devices in series with respect to airflow in a chassis.

Further, in one or more embodiments of the invention, a plurality of semiconductor devices may be cooled nearly equally. Further, in one or more embodiments of the invention, an absolute value of a cooling capacity may be large enough to achieve a target cooling capacity for a plurality of processors.

In one or more embodiments of the invention, because a second semiconductor device may be cooled as effectively as a first semiconductor device when placed in series in a chassis, fewer constraints limit the design of the chassis and components in the chassis.

In one or more embodiments of the invention, by creating a second cooling structure that is larger than a first cooling structure in a chassis, equal cooling on the both cooling structures may be achieved.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An apparatus, comprising:
a first processor in a chassis;
a first cooling structure associated with the first processor;
a second processor in the chassis; and
a second cooling structure associated with the second processor,
wherein the first cooling structure and the second cooling structure are configured such that air passing through the chassis comprises:
air that passes through the first cooling structure and the second cooling structure; and
air that passes only through the second cooling structure.

2. The apparatus of claim 1, wherein:
the second cooling structure has a greater height than the first cooling structure.

3. The apparatus of claim 1, wherein:
the second cooling structure has a greater width than the first cooling structure.

4. The apparatus of claim 1, wherein:
the first and second cooling structures are heat sinks.

5. The apparatus of claim 4, wherein:
the second heat sink has a greater fin area than the first heat sink.

6. The apparatus of claim 4, wherein:
the second heat sink has a smaller fin pitch than the first heat sink.

7. The apparatus of claim 1, further comprising:
one or more fans configured to propagate air through the chassis.

8. The apparatus of claim 7, wherein:
the one or more fans are configured to propagate air through the first and second cooling structure.

9. The apparatus of claim 1, further comprising:
a duct configured to direct air passing through the chassis to the second cooling structure.

10. The apparatus of claim 1, further comprising:
the duct configured to separate air passing through the first cooling structure and the second cooling structure from air passing only through the second cooling structure.

11. A method for cooling electronic components, comprising:
disposing a first cooling structure associated with a first processor in a chassis;
disposing a second cooling structure associated with a second processor in the chassis;
configuring the first cooling structure and the second cooling structure such that air propagating through the chassis comprises:
air that passes through the first cooling structure and the second cooling structure, and
air that passes only through the second cooling structure.

12. The method of claim 11, further comprising:
propagating air through the chassis.

13. The method of claim 12, further comprising:
propagating air through the first and second cooling structures.

14. The method of claim 11, wherein:
the second cooling structure has a greater height than the first cooling structure.

15. The method of claim 11, wherein:
the second cooling structure has a greater width than the first cooling structure.

16. The method of claim 11, wherein:
the first and second cooling structures are heat sinks.

17. The method of claim 11, further comprising:
directing air passing through the chassis to the second cooling structure.

18. The method of claim 11, further comprising:
separating air passing through the first cooling structure and the second cooling structure from air passing only through the second cooling structure.

19. Means for cooling electronic components, comprising:
means for disposing a first cooling structure associated with a first processor in a chassis;
means for disposing a second cooling structure associated with a second processor in the chassis; and
means for configuring the first cooling structure and the second cooling structure such that air propagating through the chassis comprises:
air that passes through the first cooling structure and the second cooling structure, and
air that passes only through the second cooling structure.
